(19) United States
(12) Patent Application Publication
(10) Pub. No.: US 2013/0107464 A1
(43) Pub. Date: May 2, 2013

(54) AC/DC POWER SUPPLY APPARATUS

(71) Applicant: Mu-Chun LIN, Taichung City (TW)

(72) Inventor: Mu-Chun LIN, Taichung City (TW)

(21) Appl. No.: 13/287,316

(22) Filed: Nov. 2, 2011

(51) Int. Cl. H05K 5/03

(52) U.S. Cl. 361/725

(57) ABSTRACT

An AC/DC power supply apparatus includes a hollow casing and a power conversion unit. The hollow casing includes an upright partition therein. The power conversion unit is mounted on the upright partition. The power conversion unit converts alternating current into direct current. The hollow casing includes a detachable casing plate at one side thereof relative to one side of the upright partition. The power supply apparatus of the present invention can decrease loss of current during transmission. When the power conversion unit is damaged, the casing plate can be disassembled for replacement of the damaged electronic parts of the power conversion unit.

### BACKGROUND OF THE INVENTION

1. Field of the Invention

The present invention relates to a power supply apparatus, and more particularly to an AC/DC power supply apparatus.

2. Description of the Prior Art

A conventional AC/DC power supply device is composed of many electronic parts and uses a cabinet to accommodate its parts. The cabinet has a plurality of partitions to form a plurality of chambers. The electronic parts can be placed in the chambers in order and electrically connected for converting alternating current into direct current. After a period of time, the electronic parts of the power supply device may malfunction, such as the power transistor (IGBT). It is inconvenient for the user to replace the damaged part because the arrangement of the electronic parts in the conventional power supply device. Accordingly, the inventor of the present invention has devoted himself based on his many years of practical experiences to solve these problems.

### SUMMARY OF THE INVENTION

The primary object of the present invention is to provide an AC/DC power supply apparatus which is convenient for the user to replace a damaged electronic part and can decrease loss of current during transmission.

The AC/DC power supply apparatus of the present invention comprises a hollow casing and a power conversion unit. The hollow casing comprises an upright partition therein. The upright partition has two sides defined as a first side and a second side. The hollow casing further comprises a detachable casing plate at one side thereof relative to the first side of the upright partition. The upright partition is provided with a plurality of transverse partitions extending from the second side of the upright partition. The power conversion unit is disposed on the first side of the upright partition. The power conversion unit converts alternating current into direct current.

Thereby, the power supply apparatus of the present invention can decrease loss of current during transmission when the power conversion unit converts alternating current into direct current. When the power conversion unit is damaged, the casing plate can be disassembled for replacement of the damaged electronic parts of the power conversion unit.

### BRIEF DESCRIPTION OF THE DRAWINGS

FIG. 1 is a perspective view according to a preferred embodiment of the present invention;

FIG. 2 is an exploded view according to the preferred embodiment of the present invention;

FIG. 3 is a side view according to the preferred embodiment of the present invention;

FIG. 4 is another side view according to the preferred embodiment of the present invention; and

FIG. 5 is a schematic view showing the flow of current according to the preferred embodiment of the present invention.

### DETAILED DESCRIPTION OF THE PREFERRED EMBODIMENTS

Embodiments of the present invention will now be described, by way of example only, with reference to the accompanying drawings.

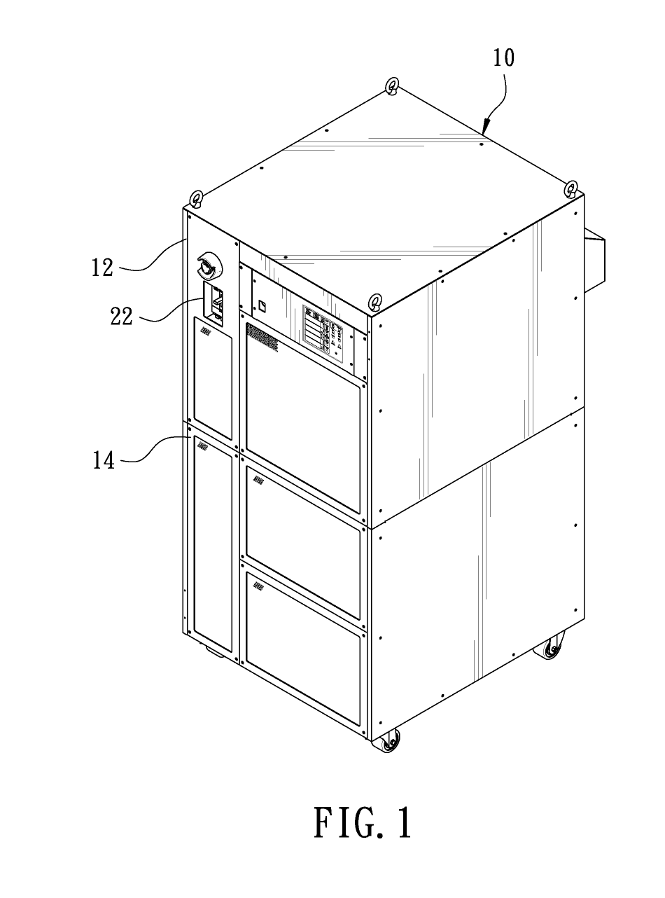

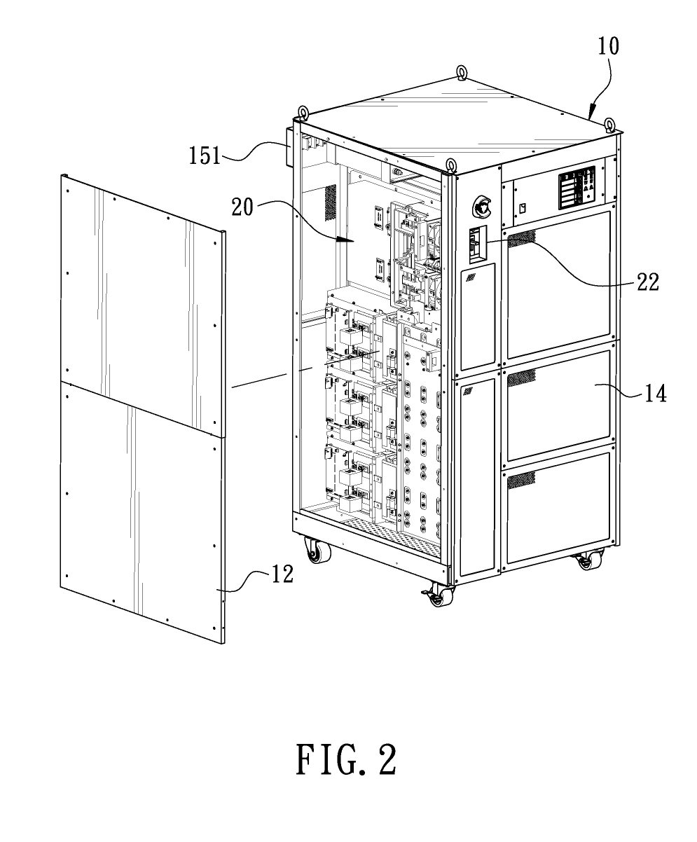

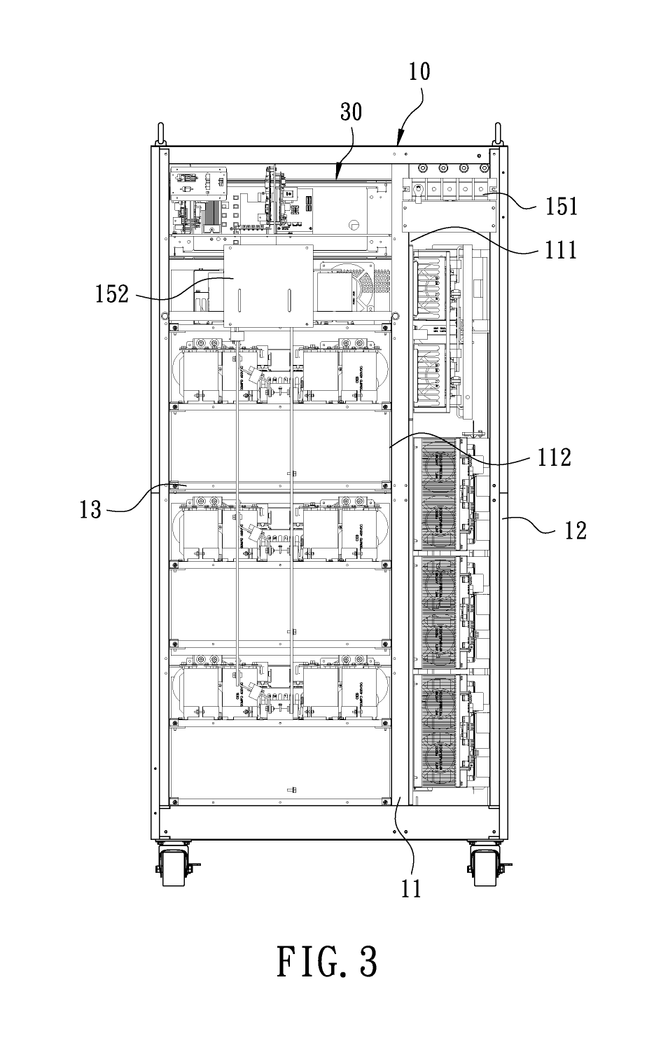

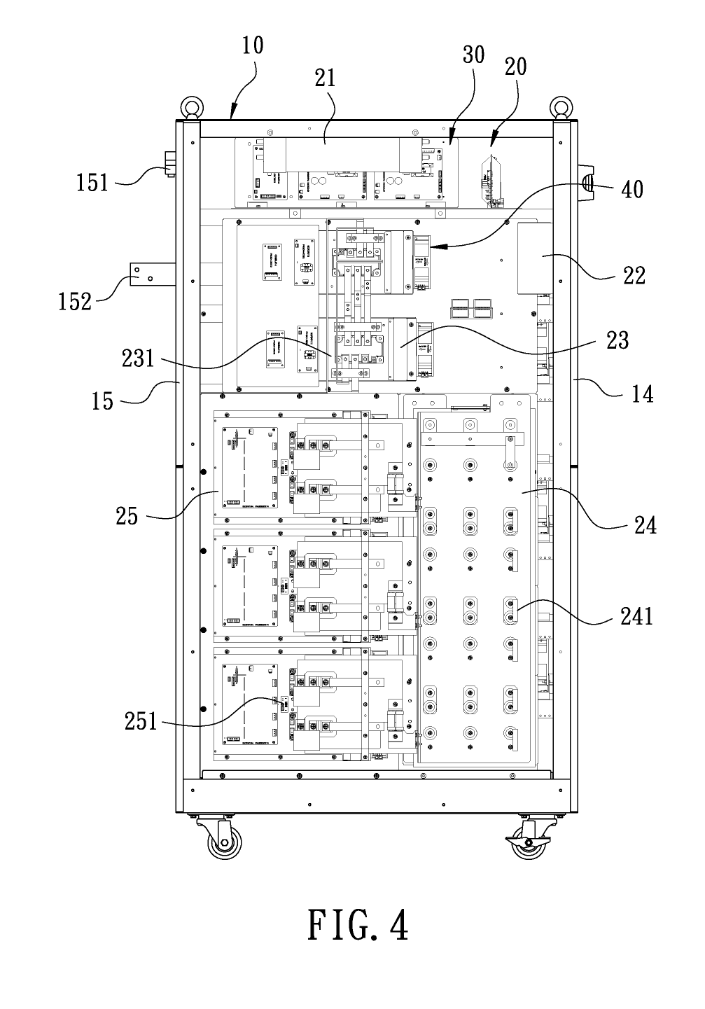

As shown in FIG. 1 through FIG. 4, the AC/DC power supply apparatus according to a preferred embodiment of the present invention comprises a hollow casing 10 and a power conversion unit 20.

The hollow casing 10 is a rectangular casing and has an upright partition 11 which is disposed close to one side of the hollow casing 10. The upright partition 11 has two sides defined as a first side 111 and a second side 112. The hollow casing 10 comprises a detachable casing plate 12 which is located opposite the first side 111 and a plurality of transverse partitions 13 which extend from the second side 112. The hollow casing 10 further comprises a front casing plate 14 and a rear casing plate 15 which is opposite the front casing plate 14. The rear casing plate 15 is provided with an input terminal stand 151 and an output bus 152.

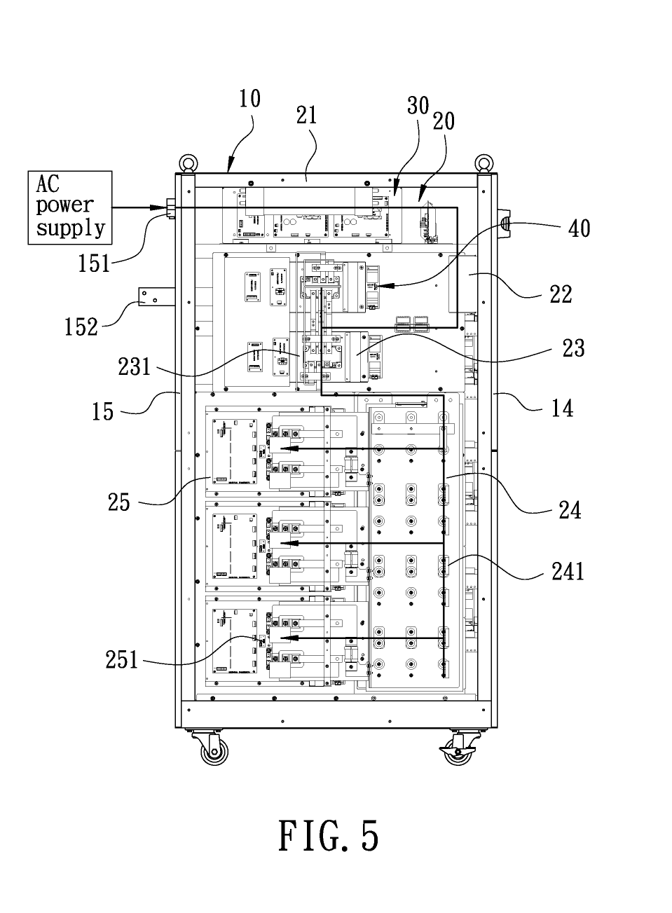

The power conversion unit 20 is disposed on the first side 111 of the upright partition 11, which is used to convert alternating current into direct current. FIG. 5 is a schematic view showing the flow of current according to the preferred embodiment of the present invention. In this embodiment, the power conversion unit 20 comprises a wave filter 21, a power switch 22, a rectification module 23, a capacitor unit 24, and a power module 25 which are connected and disposed on the upright partition 11 in sequence from top to bottom.

The wave filter 21 is disposed on an upper section of the upright partition 11. One end of the wave filter 21 is electrically connected with the input terminal stand 151 to receive the utility AC power source. The wave filter 21 is to filter out the electromagnetic interference of the AC power source.

The power switch 22 is disposed on the upper section of the upright partition 11 and located under the wave filter 21 and is exposed out of the front casing plate 14. Two ends of the power switch 22 are electrically connected with another end of the wave filter 21 and one end of the rectification module 23, respectively. The power switch 22 is used to control conduction of the wave filter 21 and the rectification module 23. If the power conversion unit 20 malfunctions, the user can switch the power switch 22 for the power supply apparatus to be a broken circuit, preventing the other electronic parts from being damaged.

The rectification module 23 is disposed on the upper section of the upright partition 11 and located at the left of the power switch 22 to receive the alternating current from the power switch 22. The rectification module 23 comprises two rectifiers 231 to convert the alternating current into direct current for output.

The capacitor unit 24 is disposed on a lower section of the upright partition 11 and located under the rectification module 23. One end of the capacitor unit 24 is electrically connected with another end of the rectification module 23. The capacitor unit 24 comprises a plurality of capacitors 241 to stabilize the direct current from the rectification module 23 and to filter out the electromagnetic interference of high frequency, so that the outputted direct current has no noise.

The power module 25 is disposed on the lower section of the upright partition 11 and located at the left of the capacitor unit 24. Two ends of the power module 25 are electrically connected with another end of the capacitor unit 24 and the output bus 152, respectively. The power module 25 comprises a plurality of power transistors 251 which are used to control the volume of the outputted direct current. Through the output bus 152, the direct current is outputted for use of an external electric appliance.

The AC/DC power supply apparatus further comprises a system control module 30 which is disposed on the transverse partitions 13 and electrically connected with the power conversion unit 20 to integrate operation of the power conversion unit 20.

As shown in the drawings, the power supply apparatus of the present invention comprises the hollow casing 10 having the upright partition 11 therein. The upright partition 11 is located at one side of the hollow casing 10. The electronic parts of the power conversion unit 20 are installed on the first side 111 of the upright partition 11 in order, and they are electrically connected each other. The present invention can be connected with an external alternating current through the input terminal stand 151, and convert the alternating current into direct current through the power conversion unit 20, and output the direct current through the output bus 152 for use of an external electric appliance.

It is noted that the electronic parts of the power conversion unit 20 are all mounted on the upright partition 11 to decrease loss of current during transmission. The power conversion unit 20 is composed of high-voltage electronic parts. Dust may accumulate on the surface of the power conversion unit 20, which results in a bad heat dissipation effect. Sometimes, the accumulated dust may cause a short circuit and damage of the power conversion unit 20. The power conversion unit 20 is mounted on the upright partition 11 in an upright way to decrease the dust accumulated on the surface of the power conversion unit 20. Furthermore, the upright partition 11 is provided with a fan unit 40 which is located in front of the power conversion unit 20, so that the dust won't accumulate on the power conversion unit 20. The power conversion unit 20 of the present invention provides a better heat dissipation effect to have a long service life. When one of the electronic parts of the power conversion unit 20 is damaged, the casing plate 12 of the hollow casing 10 can be detached for replacement of the damaged electronic part. It is very convenient for maintenance.

The features and effects of the power supply apparatus of the present invention are as follows:

1. The power conversion unit which may be damaged with ease is installed on the upright partition. When the power conversion unit is damaged, the relative casing plate can be disassembled for maintenance.

2. The power conversion unit is mounted on the upright partition in an upright way to decrease the dust accumulated on the surface of the power conversion unit. The fan unit in front of the power conversion unit can ventilate the inside of the casing to dissipate heat effectively and to decrease the accumulated dust.

3. The power conversion unit is mounted on the upright partition, which can decrease loss of current during transmission and lower interference of external electromagnetic noise.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. An AC/DC power supply apparatus, comprising:
a hollow casing comprising an upright partition therein, the upright partition having two sides defined as a first side and a second side, the hollow casing comprising a detachable casing plate at one side thereof relative to the first side of the upright partition, the upright partition being provided with a plurality of transverse partitions extending from the second side of the upright partition; and
a power conversion unit disposed on the first side of the upright partition, the power conversion unit converting alternating current into direct current.

2. The AC/DC power supply apparatus as claimed in claim 1, wherein the power conversion unit comprises a wave filter, a power switch, a rectification module, a capacitor unit and a power module, the wave filter, the power switch and the rectification module being disposed on an upper section of the upright partition and connected in sequence from top to bottom, the capacitor unit and the power module being disposed on a lower section of the upright partition and connected in parallel, one end of the wave filter being electrically connected with one end of the power switch, another end of the power switch being electrically connected with one end of the rectification module, another end of the rectification module being electrically with one end of the capacitor unit, another end of the capacitor unit being electrically connected with one end of the power module.

3. The AC/DC power supply apparatus as claimed in claim 2, wherein the hollow casing comprises another casing plate which is provided with an input terminal stand and an output bus, the power conversion unit being connected between the input terminal stand and the output bus, the input terminal stand being electrically connected with the wave filter, the output bus being electrically connected with the power module.

4. The AC/DC power supply apparatus as claimed in claim 1, further comprising a system control module which is disposed on the transverse partitions and electrically connected with the power conversion unit to integrate operation of the power conversion unit.
